(19) United States
(12) Patent Application Publication
(10) Pub. No.: US 2019/0257984 A1
(43) Pub. Date: Aug. 22, 2019

(54) ELECTRICALLY-STRETCHABLE PLANAR OPTICAL ELEMENTS USING DIELECTRIC ELASTOMER ACTUATORS

(71) Applicants: Alan Jenting SHE, Cambridge, MA (US); Shuyan ZHANG, Cambridge, MA (US); Samuel SHIAN, Cambridge, MA (US); David R. CLARKE, Cambridge, MA (US); Federico CAPASSO, Cambridge, MA (US); PRESIDENT AND FELLOWS OF HARVARD COLLEGE, Cambridge, MA (US)

(72) Inventors: Alan Jenting SHE, Cambridge, MA (US); Shuyan ZHANG, Cambridge, MA (US); Samuel SHIAN, Cambridge, MA (US); David R. CLARKE, Cambridge, MA (US); Federico CAPASSO, Cambridge, MA (US)

(73) Assignee: PRESIDENT AND FELLOWS OF HARVARD COLLEGE, Cambridge, MA (US)

(21) Appl. No.: 16/307,935

(22) PCT Filed: Jun. 9, 2017
(86) PCT No.: PCT/US2017/036897

§ 371 Date: Dec. 6, 2018

Related U.S. Application Data
(60) Provisional application No. 62/347,710, filed on Jun. 9, 2016.

(51) Int. Cl. G02B 3/14; G02B 1/04; G02B 27/01; G02C 7/08; G02B 5/18; G02B 5/30; G02C 7/04; H01L 41/047

(52) U.S. Cl. CPC G02B 3/14; G02B 1/043; G02B 27/0172; G02C 7/083; G02B 2027/0178; G02B 5/3025; G02C 7/049; H01L 41/0478; G02B 5/18

(57) ABSTRACT

An electrically-variable optical device includes a planar optical element (POE) and at least one electromechanical layer. The POE includes at least one optical layer. The at least one electromechanical layer is configured to spatially deform the POE to change an optical parameter of the POE. The at least one electromechanical layer may include a dielectric elastomer actuator (DEA) which includes electrodes and an elastomeric spacer between the electrodes. An electric field may be introduced between the electrodes to deform the spacer, which in turn deforms the POE.

### CROSS-REFERENCE TO RELATED APPLICATIONS

This application claims the benefit of and priority to U.S. Provisional Patent Application 62/347,710, filed Jun. 9, 2016, which is incorporated herein by reference in its entirety.

### STATEMENT OF FEDERALLY SPONSORED RESEARCH OR DEVELOPMENT

This invention was made with Government support under FA9550-14-1-0389, awarded by the Air Force Office of Scientific Research. The Government has certain rights in the invention.

### BACKGROUND

Conventional optical components such as lenses are manufactured by glass polishing. The limitations include bulky sizes, high manufacturing costs and limited manufacturing precisions. The limitations prevent the optical components from being used in various applications, in particular portable systems and conformal or wearable devices. Furthermore, the performance of the optical components may suffer from aberrations (e.g., chromatic aberration or spherical aberration).

### SUMMARY

According to some embodiments of the present disclosure, an optical device includes one or more planar optical elements (POEs) that are thin, flat devices replacing bulky optical devices such as lenses. Through design of the POEs for phase, amplitude, and polarization of optical wavefronts, the POEs may replace currently recognizable bulky optical devices. The optical device includes a mechanism to electrically control a POE to vary one or more optical parameters of the POE during use. For example, the optical device may include an actuator. By applying a voltage or current to the actuator, the optical device has a capability of in-plane stretching of the POE through the actuator. The stretching of the POE causes a change of one or more optical parameters, such as a focal length of the POE. Thus, according to some embodiments of the present disclosure, compact optical devices, e.g., electrically-variable varifocal flat lenses, can be constructed.

According to at least some embodiments of the present disclosure, an electrically-variable optical device includes a POE and at least one electromechanical layer. The POE includes at least one optical layer. The at least one electromechanical layer is configured to spatially deform the POE to change an optical parameter of the POE. The at least one electromechanical layer may include a dielectric elastomer actuator (DEA) which includes electrodes and an elastomeric spacer between the electrodes. An electric field may be introduced between the electrodes to deform the spacer, which in turn deforms the POE.

### BRIEF DESCRIPTION OF THE DRAWINGS

Aspects of some embodiments of the present disclosure are best understood from the following detailed description when read with the accompanying figures. It is noted that various structures may not be drawn to scale, and dimensions of the various structures may be arbitrarily increased or reduced for clarity of discussion.

FIG. 1 illustrates an example of an optical system according to various embodiments of the present disclosure.

FIG. 2 illustrates an example of a computing device according to various embodiments of the present disclosure.

FIG. 3A illustrates an example of a dielectric elastomer actuator according to various embodiments of the present disclosure.

FIG. 3B illustrates examples of electrically-variable optical devices according to various embodiments of the present disclosure.

FIG. 3C illustrates examples of electrically-variable optical devices according to various embodiments of the present disclosure.

FIG. 3D illustrates examples of electrically-variable optical devices according to various embodiments of the present disclosure.

FIG. 3E illustrates examples of uses of electrically-variable optical devices according to various embodiments of the present disclosure.

FIG. 3F illustrates examples of uses of electrically-variable optical devices according to various embodiments of the present disclosure.

FIG. 3G illustrates examples of uses of electrically-variable optical devices according to various embodiments of the present disclosure.

FIG. 3H illustrates examples of electrically-variable optical devices according to various embodiments of the present disclosure.

FIG. 3I illustrates examples of electrically-variable optical devices according to various embodiments of the present disclosure.

FIG. 3J illustrates examples of electrically-variable optical devices according to various embodiments of the present disclosure.

FIG. 3K illustrates examples of electrically-variable optical devices according to various embodiments of the present disclosure.

FIG. 4A illustrates optical parametric measurements of electrically-variable optical devices according to various embodiments of the present disclosure.

FIG. 4B illustrates optical parametric measurements of electrically-variable optical devices according to various embodiments of the present disclosure.

FIG. 4C illustrates optical parametric measurements of electrically-variable optical devices according to various embodiments of the present disclosure.

FIG. 4D illustrates optical parametric measurements of electrically-variable optical devices according to various embodiments of the present disclosure.

FIG. 4E illustrates optical parametric measurements of electrically-variable optical devices according to various embodiments of the present disclosure.

FIG. 4F illustrates optical parametric measurements of electrically-variable optical devices according to various embodiments of the present disclosure.

FIG. 5 illustrates an example of stretching of an optical portion of an electrically-variable optical device according to various embodiments of the present disclosure.

FIG. 6 illustrates a comparison of phase profiles of an electrically-variable optical device at rest and stretched according to various embodiments of the present disclosure.

FIG. 7A illustrates changes in focal length of an electrically-variable optical device for different stretch factors according to various embodiments of the present disclosure.

FIG. 7B illustrates changes in focal length of an electrically-variable optical device for different stretch factors according to various embodiments of the present disclosure.

FIG. 7C illustrates changes in focal length of an electrically-variable optical device according to various embodiments of the present disclosure.

FIG. 7D illustrates an example of an electrode layout of an electrically-variable optical device according to various embodiments of the present disclosure.

FIG. 7E illustrates photographs of an electrode layout of an electrically-variable optical device according to various embodiments of the present disclosure.

FIG. 7F illustrates measurements of an example of an electrode layout of an electrically-variable optical device according to various embodiments of the present disclosure.

FIG. 8 illustrates an example of an electrically-variable optical device according to various embodiments of the present disclosure.

FIG. 9 illustrates an example of an optical system incorporating two electrically-variable optical devices according to various embodiments of the present disclosure.

FIG. 10 illustrates an example of eyewear incorporating two electrically-variable optical devices according to various embodiments of the present disclosure.

Common reference numerals are used throughout the drawings and the detailed description to indicate the same or similar elements. Embodiments of the present disclosure will be more apparent from the following detailed description taken in conjunction with the accompanying drawings.

### DETAILED DESCRIPTION

According to at least some embodiments of the present disclosure, an optical system includes one or more POEs and one or more actuators for achieving highly variable (e.g., tunable) optics. The disclosed system manifests high efficiency, controllability, repeatability, and ruggedness. In addition, the disclosed system, tuned by at least one actuator, may achieve a broadband response, particularly in the visible spectrum. The disclosed system is readily available for large-area fabrication.

As used herein, the term “visible spectrum” refers to wavelengths visible to humans. For example, the visible spectrum may encompass wavelengths between about 400 nm to about 700 nm. Additionally, the meta-lenses described herein may be optimized for certain subranges of the visible spectrum, or for certain ranges out of the visible spectrum (e.g., infrared (IR) or near-infrared (NIR) spectrums).

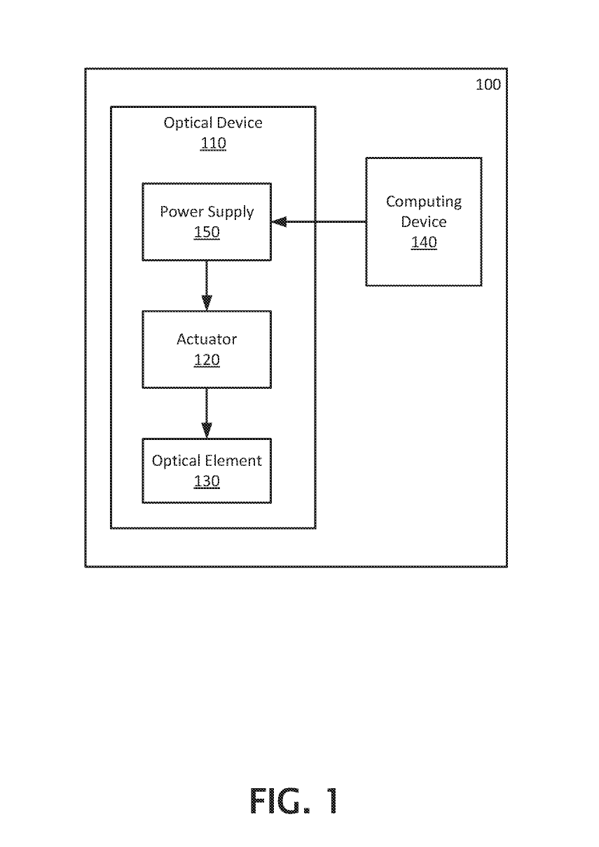

FIG. 1 illustrates an optical system 100 providing for highly variable optics, according to some embodiments of the present disclosure. Optical system 100 includes an optical device 110, which includes an actuator 120 and an optical element 130. Optical system 100 further includes a computing device 140 and a power source 150 (also referred to as power supply). Power source 150 is shown as being included in optical device 110, but may instead be external to optical device 110. Power source 150 provides power to actuator 120. Computing device 140 controls power (e.g., electric power) from power source 150 to actuator 120, which in turn varies one or more parameters of optical element 130. Optical device 110, actuator 120, and optical element 130 are described by way of example embodiments below.

At least portions of, or all of, computing device 140 may be incorporated into optical device 110, or may be external to optical device 110. Computing device 140 may be connected to multiple optical devices 110, or multiple portions of optical device 110, such as for improved granularity of control or for different control of different optical devices 110 (e.g., to control different parameters in each of different ones of multiple stacked optical devices 110). Components of computing device 140 may be implemented in hardware, firmware or software, or a combination of two or more of hardware, firmware or software. Hardware may include, for example, integrated circuits and/or discrete circuitry. Firmware indicates software that is encoded in hardware, or software that is programmed once and not generally reprogrammable. Other software is reprogrammable, such as through a serial or parallel interface, or through pins of a circuit. In some embodiments, computing device 140 is an integrated circuit that is integrated with optical device 110 in a single component or a single device.

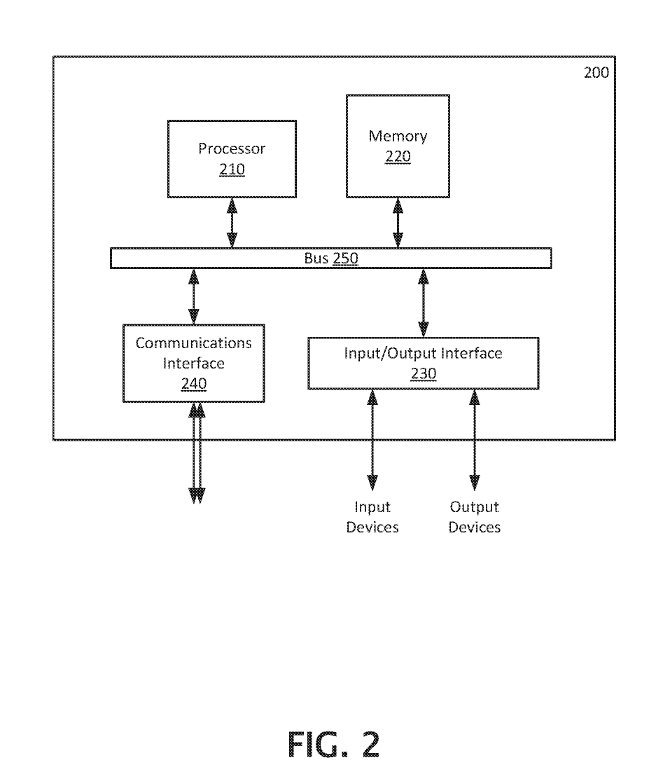

FIG. 2 generally illustrates an example of a computing device 200 (e.g., computing device 140) that includes a processor 210, a memory 220, an input/output (I/O) interface 230, and a communication interface 240. A bus 250 provides a communication path between two or more of the components of computing device 200. The components shown are provided by way of illustration and are not limiting. Computing device 200 may have additional or fewer components, or multiple of the same component.

Processor 210 represents one or more of a processor, microprocessor, microcontroller, application-specific integrated circuit (ASIC), and/or field-programmable gate array (FPGA), along with associated logic.

Memory 220 represents one or both of volatile and non-volatile memory for storing information. Examples of memory include semiconductor memory devices such as EPROM (erasable programmable read-only memory), EEPROM (electrically erasable programmable read-only memory), RAM (random-access memory), and flash memory devices, discs such as internal hard drives, removable hard drives, magneto-optical, CD (Compact Disc), DVD (digital versatile disc), and Blu-ray discs, memory sticks, and the like.

At least portions of optical system 100 of this disclosure may be implemented as computer-readable instructions in memory 220 of computing device 200, executed by processor 210.

Input/output interface 230 represents electrical components and optional code that together provides an interface from the internal components of computing device 200 to external components. Examples include a driver integrated circuit with associated programming.

Communications interface 240 represents electrical components and optional code that together provides an interface from the internal components of computing device 200 to external networks.

Bus 250 represents one or more interfaces between components within computing device 200. For example, bus 250 may include a dedicated connection between processor 210 and memory 220 as well as a shared connection between processor 210 and multiple other components of computing device 200.

Some embodiments of the disclosure relate to a non-transitory computer-readable storage medium having computer code thereon for performing various computer-implemented operations. The term “computer-readable storage medium” is used herein to include any medium that is capable of storing or encoding a sequence of instructions or computer codes for performing the operations, methodologies, and techniques described herein. The media and computer code may be those specially designed and constructed for the purposes of the embodiments of the disclosure, or they may be of the kind well known and available to those having skill in the computer software arts. Examples of computer-readable storage media include, but are not limited to: magnetic media such as hard disks, floppy disks, and magnetic tape; optical media such as CD-ROMs (Compact Disc Read-Only Memory) and holographic devices; magneto-optical media such as optical disks; and hardware devices that are specially configured to store and execute program code, such as application-specific integrated circuits (ASICs), programmable logic devices (PLDs), and ROM and RAM devices.

Examples of computer code include machine code, such as produced by a compiler, and files containing higher-level code that are executed by a computer using an interpreter or a compiler. For example, some embodiments of the disclosure may be implemented using Java, C++, or other object-oriented programming language and development tools. Additional examples of computer code include encrypted code and compressed code. Moreover, some embodiments of the disclosure may be downloaded as a computer program product, which may be transferred from a remote computer (e.g., a server computer) to a requesting computer (e.g., a client computer or a different server computer) via a transmission channel. Another embodiment of the disclosure may be implemented in hardwired circuitry in place of, or in combination with, machine-executable software instructions.

Referring back to FIG. 1, in one or more embodiments, actuator 120 is a dielectric elastomer actuator (DEA). The DEA works as a parallel plate capacitor, having parallel plate electrodes with a compressible spacer in between. The spacer is, or includes, a soft elastomeric material, which is referred to as an “artificial muscle.” Examples of elastomeric materials include, e.g., polydimethylsiloxane (PDMS) elastomer, acrylic elastomers (e.g., a VHB elastomer from the 3M company), natural or synthetic rubber, and silicone. When the DEA is activated by applying an external voltage or current to the electrodes (e.g., a voltage applied between the electrodes), the spacer undergoes a mechanical deformation due to compression as the two electrodes are drawn together (or alternatively, undergoes decompression as the two electrodes are drawn apart). In some embodiments, the compression is in a direction of the electric field, and the corresponding expansion is perpendicular to the compression and in a direction that is substantially parallel to the parallel plate electrodes. In some embodiments, a lateral strain due to the expansion, sometimes referred to as stretch, can be as high as about 300%.

A default position for the parallel plate electrodes may be such that the spacer is in a relaxed state, is in a partially compressed state, or is in a fully compressed state (as defined by the limits of the DEA), such that actuation of the DEA results respectfully in compression from the relaxed state, compression or decompression from the partially compressed state, or decompression from the fully compressed state.

In one or more embodiments, the electrodes may be prepared from a highly transparent electrically conductive material that conducts electricity while passing (transmitting) most of the light in a visible wavelength spectrum (e.g., wavelengths of about 400 nanometers (nm) to about 700 nm). For example, an electrode material may be selected such that the material passes (transmits) greater than about 60%, about 70%, or about 80% of light in the visible wavelength spectrum. Such embodiments are applicable for optical instruments. In some other embodiments, the materials of the electrodes may be selected for transparency in other wavelength ranges for different purposes. The material of the electrode may be further selected to conduct sufficient electricity to deform the spacer.

Additionally, in one or more embodiments, the spacer (e.g., elastomer membrane) may be prepared from a transparent material (e.g., a silicone sheet or other transparent inorganic or organic elastomer). For example, a spacer material may be selected such that the material passes (transmits) greater than about 90% or about 95% of light in the visible portion of the electromagnetic spectrum (e.g., about 400-700 nm). Such membrane materials include, but are not limited to, PDMS, silicones, polyurethane, and acrylics (including acrylic elastomers such as VHB 4905 and/or VHB 4910, each produced by 3M).

In one or more embodiments in which the electrodes and spacer are transparent, a DEA may be used in optical devices with minimal impact to optical properties over many spectrums, as discussed below, allowing the disclosed technology to be applied to wavelength ranges across broadband spectrums. The disclosed optical device can be also applied to narrow band spectrums, such as narrow bands associated with chemical-specific spectral imaging (for example surveillance or monitoring systems).

In one or more embodiments, the electrodes of a DEA include graphene. In one or more embodiments, the electrodes of a DEA include single-walled carbon nanotubes (SWCNTs), providing for flexible and transparent electrodes. In some embodiments, the SWCNTs are constructed in the form of a thin SWCNT mat.

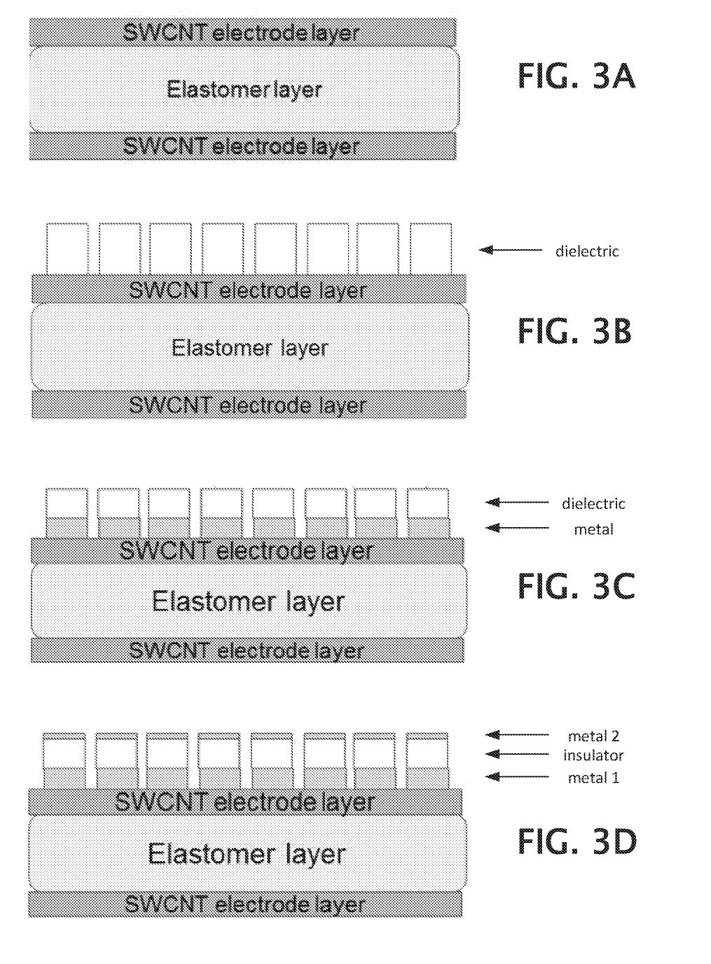

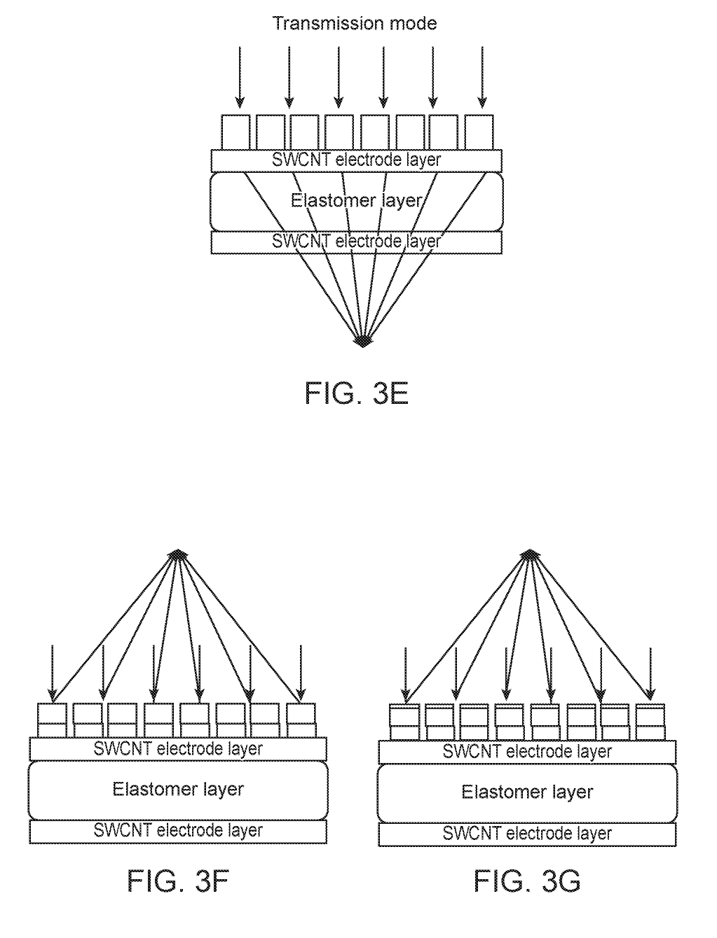

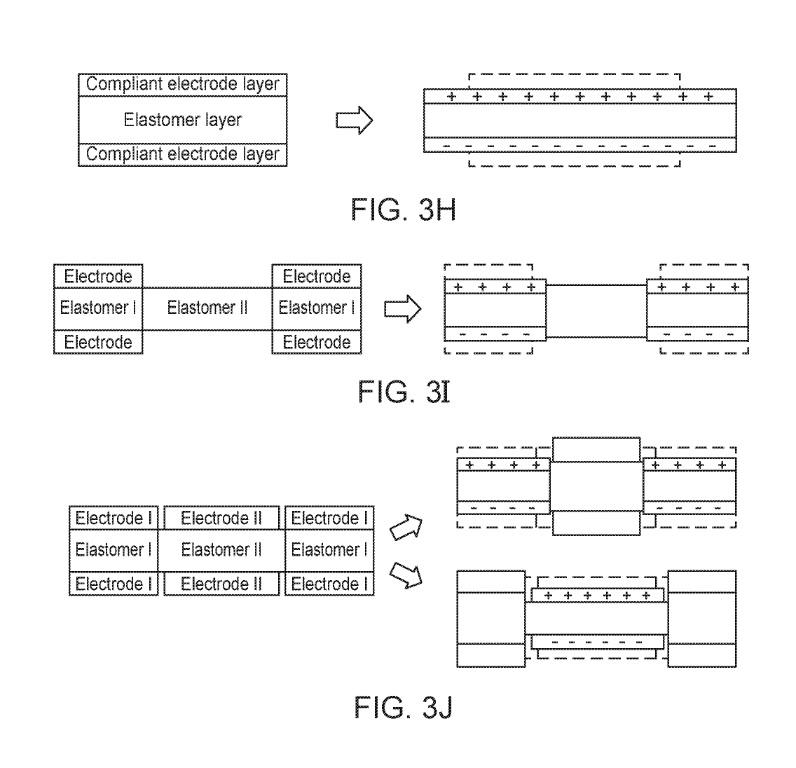

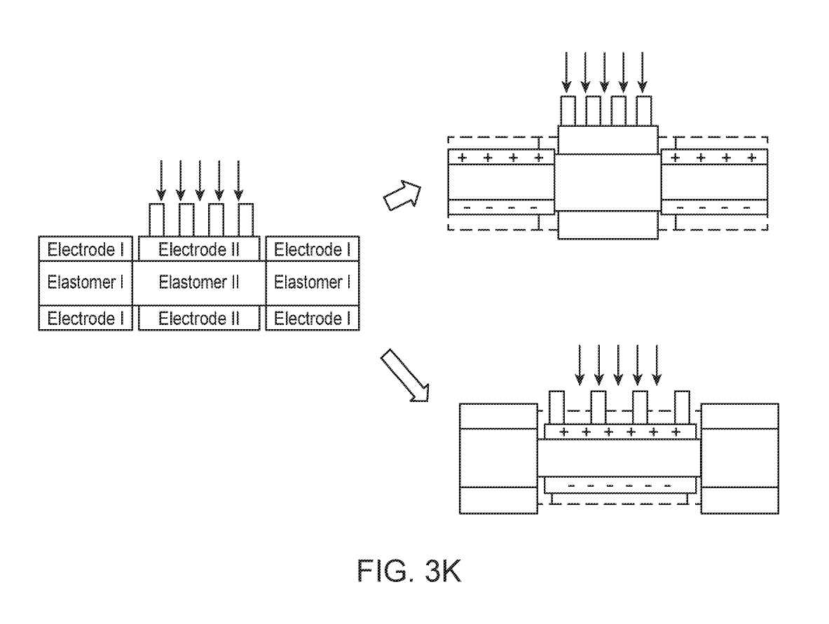

FIG. 3A illustrates an example of a construction of a DEA in which the DEA electrodes each include one or more layers of SWCNTs, and the DEA includes an elastomer spacer layer.

In some embodiments, the SWCNT DEA may be combined with one or more POEs. FIGS. 3B-3D illustrate examples of an optical device (also referred to as DEA/POE) including a POE and the SWCNT DEA of FIG. 3A.

FIG. 3B illustrates a DEA/POE including the SWCNT DEA of FIG. 3A with dielectric metasurface elements (shown as bars or posts in this example) positioned on a surface of the SWCNT DEA.

FIG. 3C illustrates a DEA/POE including the SWCNT DEA of FIG. 3A with dielectric/metal metasurface elements (shown as bars or posts in this example) positioned on a surface of the SWCNT DEA. The metasurface elements in this example each include a metal layer (next to the surface of the SWCNT DEA) and a dielectric layer on the metal layer.

FIG. 3D illustrates a DEA/POE including the SWCNT DEA of FIG. 3A with metal/insulator/metal metasurface elements (shown as bars or posts in this example) positioned on a surface of the SWCNT DEA. The metasurface elements in this example each include a first metal layer (next to the surface of the SWCNT DEA), an insulator layer on the first metal layer, and a second metal layer on the insulator layer.

FIGS. 3B-3D are illustrative, and is to be noted that a POE may include different types of metasurface elements, such as some combination of metasurface elements selected from dielectric metasurface elements, metasurface elements composed of a combination of multiple metal and insulator layers (e.g., insulator/metal elements, or metal/insulator/metal metasurface elements), insulator/insulator metasurface elements, and so forth. Further, different ones of the metasurface elements may have different shapes and/or different dimensions.

The DEA/POE optical devices as illustrated in FIGS. 3B-3D can be applied to various applications. FIGS. 3E-3G illustrate some examples of uses for the DEA/POEs of FIGS. 3B-3D.

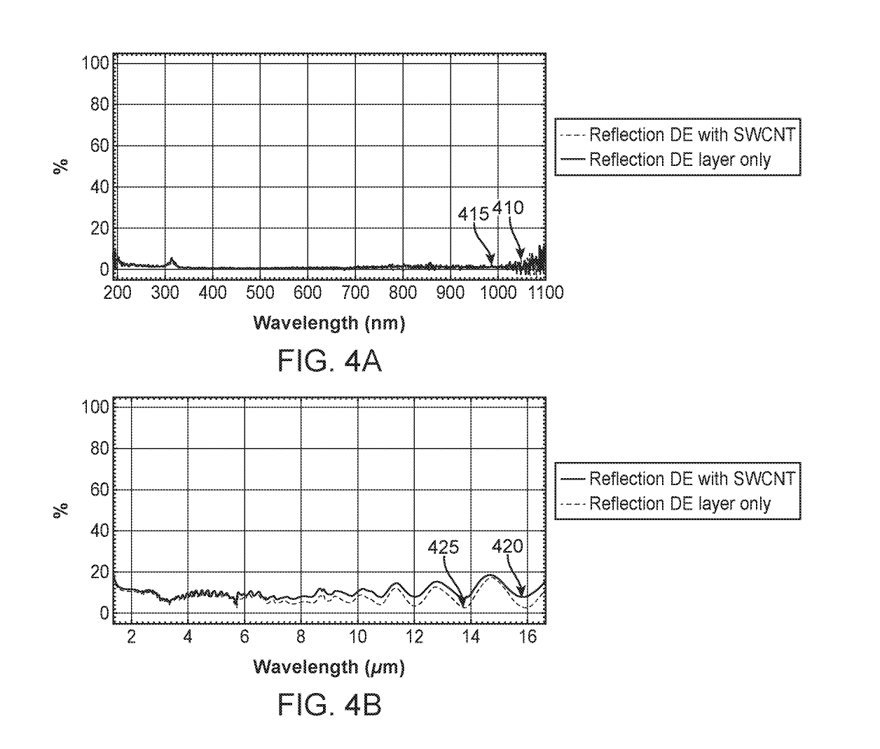

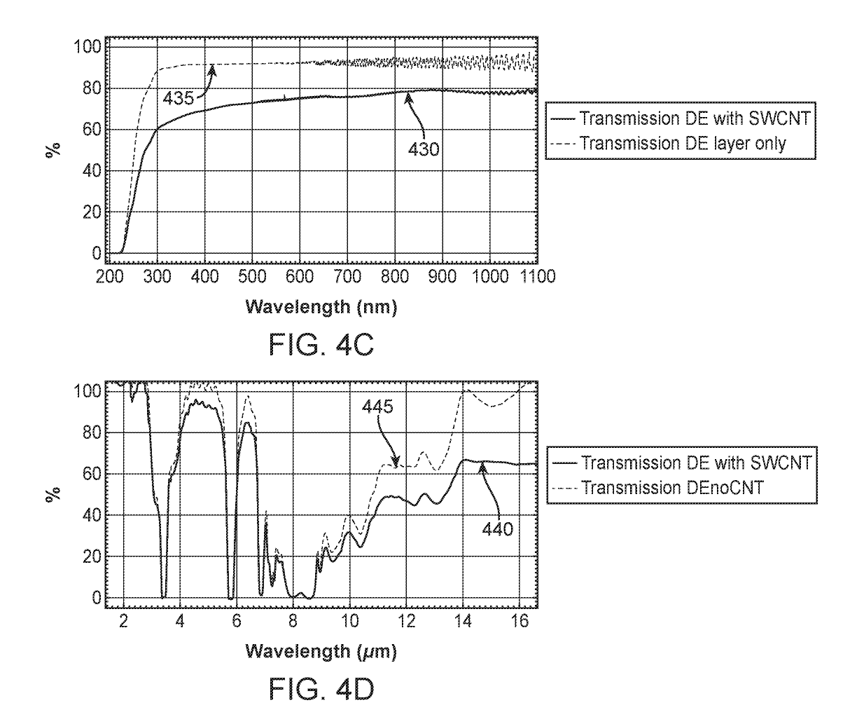

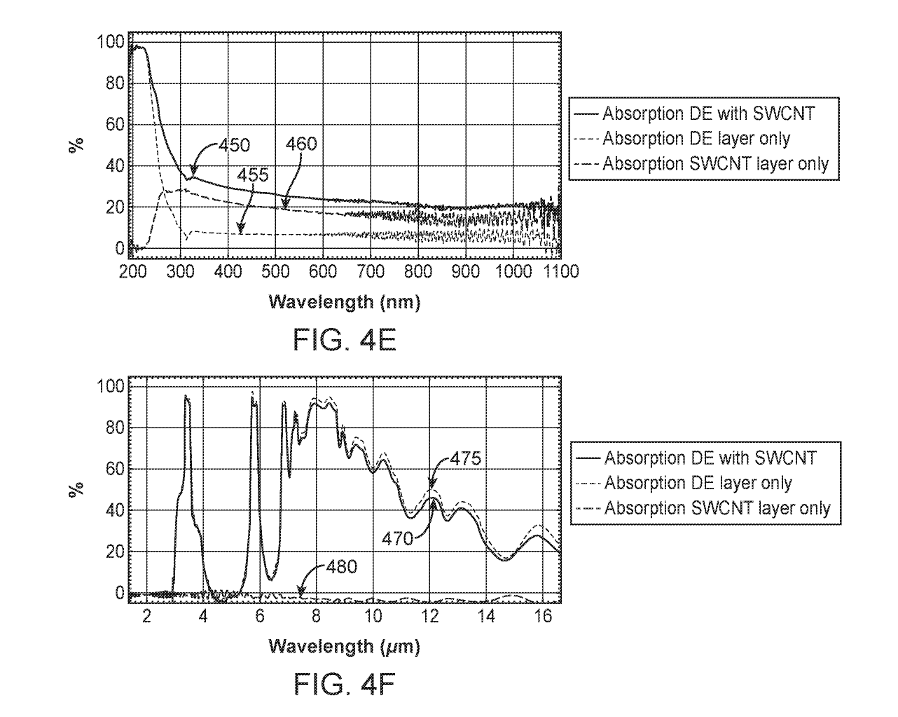

FIG. 3E illustrates the DEA/POE of FIG. 3B in a transmission mode, where energy (e.g., visible light or infrared) is applied at a surface of the SWCNT DEA opposite the surface on which the POE is disposed or attached, for transmission through the SWCNT DEA. High transmission of the dielectric elastomer and electrode layers (see FIGS. 4A-4F) results in good device efficiency characteristics in transmission. Low reflectivity of the dielectric elastomer layer and electrodes reduce undesired optical interference with the metasurface.

In some other embodiments, the DEA/POE of FIG. 3E can alternatively be used in reflection mode, similar to the examples shown in FIGS. 3F and 3G. FIG. 3F illustrates the DEA/POE of FIG. 3C in a reflection mode, where light (e.g., visible light or infrared) is incident on the SWCNT DEA on which the POE is disposed or attached, for reflection by the SWCNT DEA. The DEA/POE of FIG. 3F can alternatively be used in transmission mode, similar to the example shown in FIG. 3E.

FIG. 3G illustrates the DEA/POE of FIG. 3D in a reflection mode, where energy (e.g., visible light or infrared) is applied at a surface of the SWCNT DEA on which the POE is disposed or attached, for reflection by the SWCNT DEA. The DEA/POE of FIG. 3G can alternatively be used in transmission mode, similar to the example shown in FIG. 3E.

FIGS. 3H-3J illustrate additional examples of DEAs. FIG. 3H illustrates a DEA at rest (left) and after a potential difference is established between the electrodes (right).

In some embodiments, a DEA may include multiple elastomers. FIG. 3I illustrates an example of a construction of a DEA including an Elastomer I and an Elastomer II. Elastomer II can be either a continuous layer with Elastomer I or a different component than Elastomer I. Further, a material of Elastomer I may be the same as or different than a material of Elastomer II. In some embodiments, both Elastomer I and Elastomer II may be pre-stretched between 10% to 1000% and are attached on a frame. The DEA electrodes are placed on either side of Elastomer I. When energized with electrical charges, the electrodes compress Elastomer I in a thickness direction, which, through Poisson's relation, causes expansion to Elastomer I in a lateral direction, as illustrated. The expansion on Elastomer I causes Elastomer II to contract laterally, as illustrated in FIG. 3I (right side of the arrow).

In some embodiments, the electrode of the DEA may include multiple segments. FIG. 3J illustrates an example of a construction of a DEA in which the electrode is partitioned into two segments (e.g., concentric segments). Segment I includes Electrodes I and Elastomer I, and segment II includes Electrodes II and Elastomer II. Elastomer II can be either a continuous layer with Elastomer I or a different component than Elastomer I. Further, a material of Elastomer I may be the same as or different than a material of Elastomer II. The electrodes of each segment can be energized independently. When Electrodes I are energized, Elastomer I expands laterally, causing lateral contraction in Elastomer II. In contrast, when Electrodes II are energized, Elastomer II expands laterally, causing lateral contraction in Elastomer I.

FIG. 3K illustrates an example of a POE attached to the DEA in FIG. 3J, in a transmission mode, where photon energy (e.g., visible light or infrared) is applied at a surface of the POE and an observer of the light is located on the other side of the surface. When Electrodes I are charged, Elastomer I expands laterally, causing lateral contraction in Elastomer II and consequently reduction in the length of POE. Such reduction may increase the optical power (e.g., transmission) of the POE. Alternatively, when Electrodes II are charged, Elastomer II expands laterally, causing increase in a length of the POE. Such increase in the length may reduce an optical power (e.g., transmission) of the POE. An advantage of this configuration is an increase in dynamic range of the tuning. Another advantage is that the tuning range can operate near the optimum operating condition (e.g., minimum aberrations) in a relaxed state.

FIGS. 4A-4F provide measurements of parameters related to SWCNT DEAs such as the SWCNT DEA of FIG. 3A, where the spacer is a dielectric elastomer.

FIG. 4A illustrates reflectance measurements of the dielectric elastomer within the visible and near-infrared spectrum with (410) and without (415) SWCNT electrode layers on both sides. As shown in FIG. 4A, the SWCNT electrode layers have little impact on transmission, reflection and absorption properties in the visible spectrum. Low reflectance indicates good compatibility with POEs in both transmission and reflection modes.

FIG. 4B illustrates reflectance measurements of the dielectric elastomer within the mid-infrared spectrum with (420) and without (425) SWCNT electrode layers on both sides. As shown in FIG. 4B, the SWCNT electrode layers have little impact on transmission, reflection and absorption properties in the mid-infrared spectrum. Low reflectance indicates good compatibility with POEs in both transmission and reflection modes.

FIG. 4C illustrates transmittance measurements of the dielectric elastomer within the visible and near-infrared spectrum with (430) and without (435) SWCNT electrode layers on both sides. Measurements show high and generally broadband transmittance throughout the visible and near-infrared wavelengths. High transmittance indicates good compatibility with POEs in both transmission and reflection modes.

FIG. 4D illustrates transmittance measurements of the dielectric elastomer within the mid-infrared spectrum with (440) and without (445) SWCNT electrode layers on both sides. There may be some wavelengths in the mid-infrared spectrum that are absorbed, however, large transparency windows are shown (such as 3.9-5.5 microns and 6.0-6.7 microns), which can be utilized for making optical devices. High transmittance indicates good compatibility with POEs in both transmission and reflection modes.

FIG. 4E illustrates absorption measurements of the dielectric elastomer within the visible and near-infrared spectrum with (450) and without (455) SWCNT electrode layers on both sides, as well as absorption of the SWCNT layer alone (460). In general, absorption is low in the visible and near-infrared spectrum. Measurements indicate a large contribution to the absorption from the SWCNT layers in the visible and near-infrared spectrum.

FIG. 4F illustrates absorption measurements of the dielectric elastomer within the mid-infrared spectrum with (470) and without (475) SWCNT electrode layers on both sides, as well as absorption of the SWCNT layer alone (480). Some absorption peaks exist in the mid-infrared spectrum. Measurements indicate close to zero contribution in the mid-infrared spectrum. Lower absorption indicates higher device efficiency.

In some embodiments, POEs can control a wavefront of light by using arrays of components patterned on a surface. For example, the components may be optical phase shifters, amplitude modulators, or polarization changing components. The POE design introduces a desired spatial distribution of optical phase, amplitude, and/or polarization. By tailoring the properties of each component of a component array, the wavefront may be adjusted as it passes through the POE, by spatially controlling optical phase, amplitude, and/or polarization of the transmitted, reflected, or scattered light. Thus, replacements for lenses, axicons, blazed gratings, vortex plates and wave plates, among other optical elements, have been achieved using POEs, and generally, such optical element replacements are thin and lightweight devices by way of comparison to the optical elements replaced. Non-limiting examples of POEs include, e.g., metasurfaces (which are based on subwavelength-spaced phase shifters), wavelength-scale phased arrays, and photonic crystals.

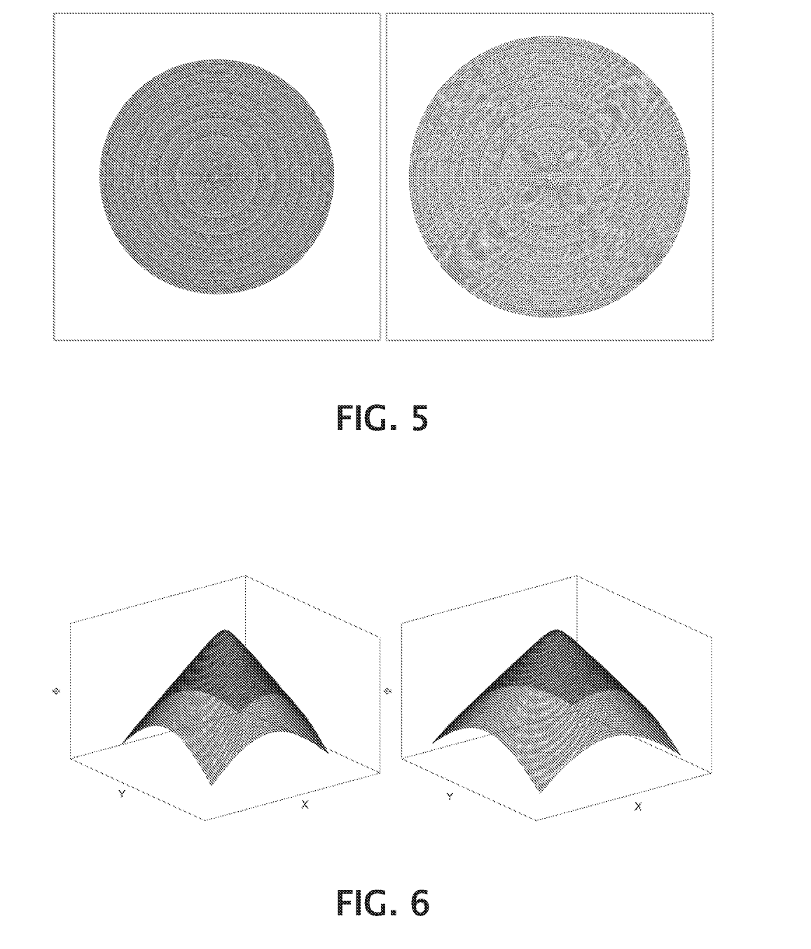

In one or more embodiments of the present disclosure, properties of a POE may be changed by stretching the POE in one or more directions. FIG. 5 illustrates an example of a POE prior to (left) and after (right) stretching with a stretch factor of about 1.2. In the example shown in FIG. 5, the POE is a metasurface flat lens, shown from a top view. Metasurface elements appear as concentric circles, but are actually an array of three-dimensional posts arranged in concentric circles. The metasurface elements alter a local phase of incident radiation according to a hyperboloidal phase profile (see Equation (1) below). As the lens is stretched, focal length scales quadratically with stretch (see Equation (3) below) such that focal length of the stretched metasurface is greater than that of the unstretched one. A tuning range of focal length also scales with stretch (see Equation (4) below).

As can be seen for the example of FIG. 5, stretching the metasurface flat lens POE by an approximately same amount in perpendicular directions (e.g., along the x and y axes in an x-y plane) uniformly scales lateral coordinates of the metasurface flat lens POE, which results in a change to a focal length of the metasurface flat lens POE while maintaining its focusing performance. Thus, a flat lens with variable focal length (e.g., zoom capability) controlled by an applied voltage or current can be realized.

Equation (1) describes a phase profile of an example lens having a hyperboloidal phase profile.

$$ϕ ( r , λ ) = - \frac{2 π}{λ} \times ( \sqrt{{r}^{2} + {f}^{2}} - f ) \qquad ( 1 )$$

Equation (2) describes a phase profile of the same example lens after uniform stretching.

$$ϕ ( r , λ , s ) = - \frac{2 π}{λ} \times ( \sqrt{{( \frac{r}{s} )}^{2} + {f}^{2}} - f ) \qquad ( 2 )$$

In both equation (1) and equation (2), λ is a wavelength of light passing through the lens, r is a radial position measured from a center of the lens, f is a focal length of the unstretched lens, and s is a stretch factor (e.g., representing a scaling of the lateral coordinates of the POE).

Equation (3) describes that as the lens is stretched, focal length scales quadratically with stretch, where f=f₀ is the unstretched focal length.

f(s)=s²f₀ (3)

Equation (4) describes that a tuning range of focal length scales with stretch factor s also.

Δf=(s²−l)f₀ (4)

FIG. 6 illustrates phase profiles for an example of a metasurface flat lens POE prior to (left) and after (right) stretching uniformly with a stretch factor of about 1.2. This illustrates that stretching in this manner maintains a hyperboloidal phase profile and hence does not introduce large aberrations in focusing.

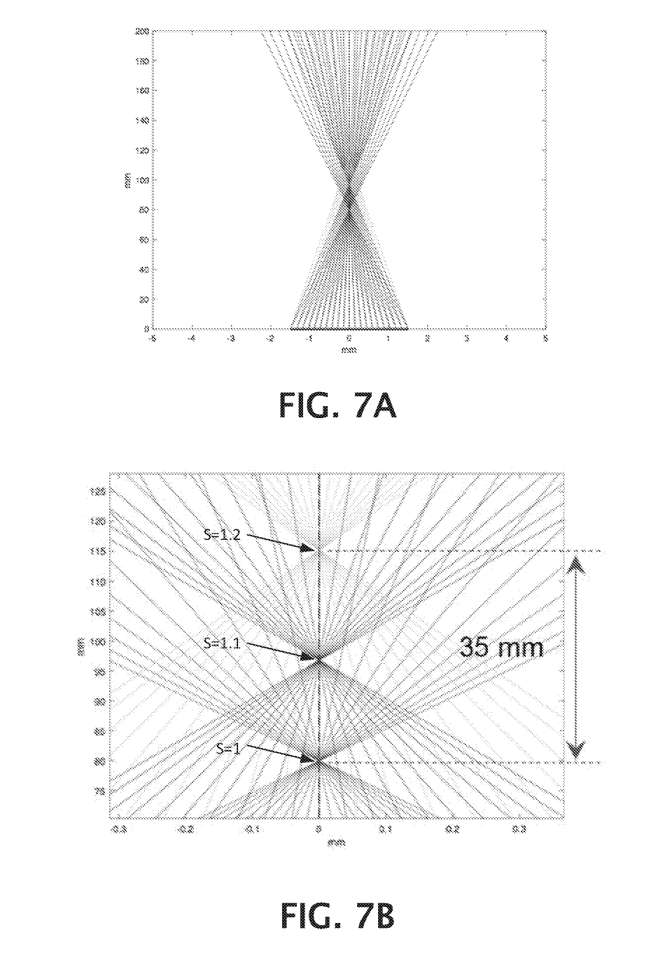

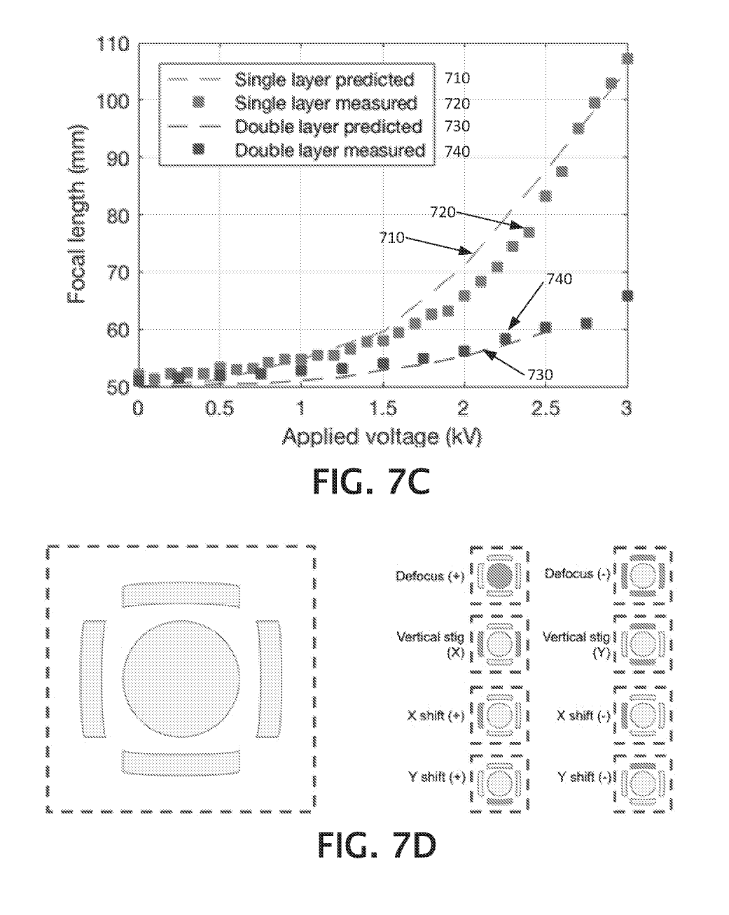

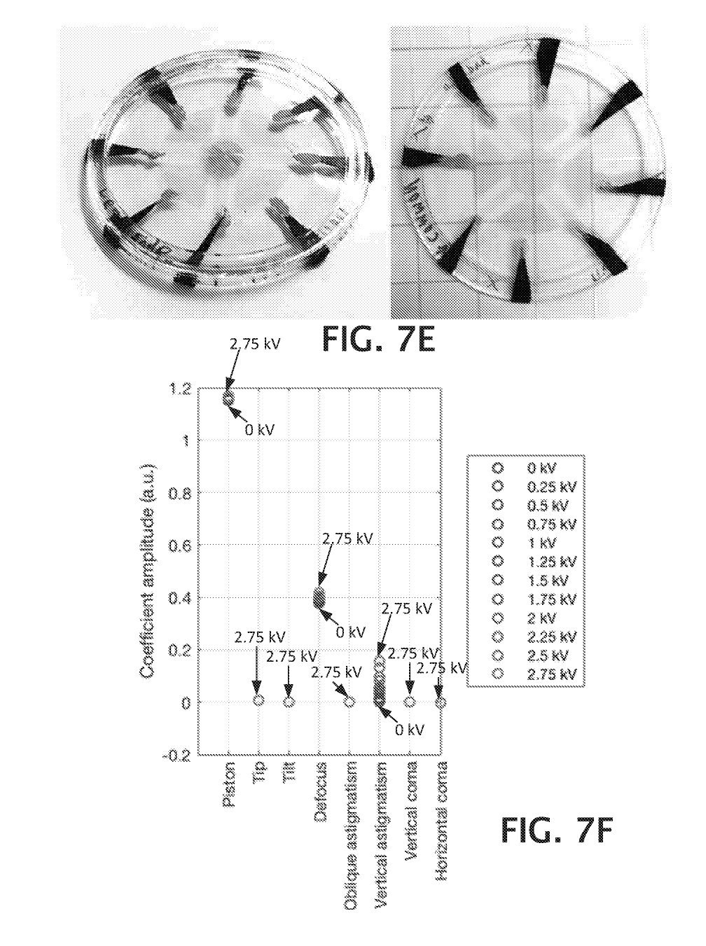

FIG. 7A illustrates results of a ray tracing calculation for a metasurface lens that is stretched by stretch factors of about 1, about 1.1, and about 1.2, valid for both transmission and reflection lenses.

FIG. 7B illustrates an enlarged view of FIG. 7A, showing nearly no aberrations (e.g., spherical aberration) introduced to the focus by stretching. A focal length of the unstretched lens is about 80 millimeters (mm) and the focal length is tuned by about 35 mm when the lens is stretched by a factor of about 1.2.

FIG. 7C illustrates experimentally measured tunable focal lengths for an example of an optical device, according to various embodiments of the present disclosure. As shown in FIG. 7C, a voltage between 0 and 3 kilovolts is applied to actuate the dielectric elastomer actuator (DEA), which causes the focal length of the metasurface lens to increase. For some embodiments shown in FIG. 7C, when one layer of elastomer material (single layer) is used, the focal length varies from 50 mm to 107 mm (dotted line 720), corresponding to a change in focal length of over 100%. For some embodiments shown in FIG. 7C, when two layers of elastomer material (double layer) are used, the focal length varies from 50 mm to 66 mm (dotted line 740). The experimental results are compared to their theoretically predicted focal lengths, calculated using measured strain values (dashed line 710 and dashed line 730, respectively): f(s)=s²f₀. As shown in FIG. 7C, the focal length of the metasurface lens can be tuned by the actuator voltage as predicted.

In some embodiments, multiple aberration corrections may be achieved simultaneously by a multi-electrode configuration. Based on the multi-electrode configuration, multiple aberration corrections may be achieved in a single optical layer (or multiple layers). For example, FIG. 7D illustrates an example of electrode layout for an electrically tunable lens that are capable of achieving multiple aberration corrections. As shown in the left portion of FIG. 7D, the tunable lens may include, e.g., five electrodes. By activating different combinations of one or more electrodes of the five electrodes (one middle electrode and four peripheral electrodes), the optical device can achieve different aberration correction functions. For example, as shown in the right portion of FIG. 7D, the optical device can activate the middle electrode or the four peripheral electrodes for achieving focusing and/or defocusing functions. The optical device can activate the left and right electrodes or the top and bottom electrodes for achieving X-axis astigmatism or Y-axis astigmatism correction functions. The optical device can activate one of the four peripheral electrodes for achieving X-axis shift tuning or Y-axis shift tuning functions. In some embodiments, the X-axis shift tuning and/or Y-axis shift tuning allow for optical image stabilization.

FIG. 7E illustrates photographs of an optical device demonstrating the electrode layout described in FIG. 7D. The left portion of FIG. 7E illustrates a photograph of the optical device, which includes a single metasurface lens (e.g., 6 mm in diameter) attached to a DEA. The DEA may include five electrodes made by single-walled carbon nanotube electrodes (SWCNTs). Carbon tape electrical contact pads are in contact with SWCNTs using silver paste. The right portion of FIG. 7E illustrates a photograph of the SWCNT electrode patches, without the metasurface lens.

FIG. 7F illustrates experimental measurements showing control of astigmatism independent of other lens parameters for an optical device of FIG. 7D. For example, the left and right electrodes of the electrode configuration in FIG. 7D are actuated with an applied voltage ranging from 0 to 2.75 kilovolts to perform astigmatism correction in the X-direction (corresponding to vertical astigmatism in terms of the Zernike polynomials (discussed below)). The first eight Zernike polynomials are measured. The data shown in FIG. 7F indicates that the vertical astigmatism may be varied while not affecting other lens characteristics, such as defocus, tip, and tilt.

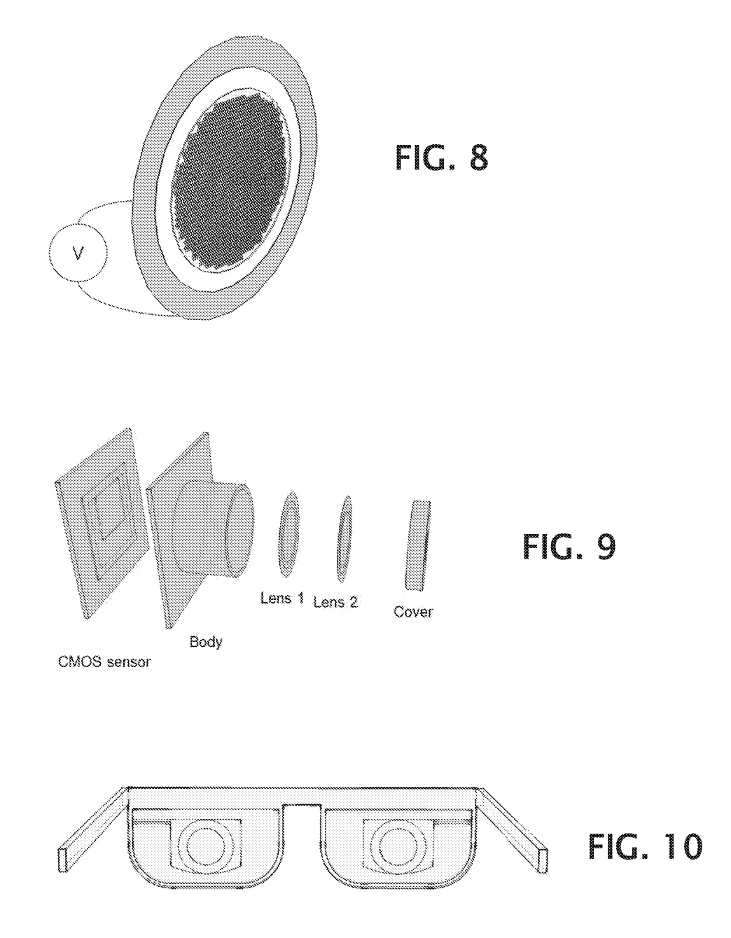

FIG. 8 illustrates an example of a DEA/POE device in which a metasurface POE is attached to a DEA formed as, e.g., a circle. The electrodes of the DEA may be shaped as, e.g., circles or rings. When the electrodes are circles, the spacer is compressed by applying a voltage between the electrodes. When the electrodes are rings, a periphery of the spacer is compressed, causing the spacer to deform in a way such that it bulges in a direction away from a plane of the rings. As the spacer stretches (with circular electrodes) or bulges (with ring electrodes), the POE stretches or bulges correspondingly, thus changing the optical properties of the POE.

FIG. 9 illustrates an example of two variable lenses (Lens 1 and Lens 2) in a stacked, compound optical system, such as a camera module in a cell phone. A separation between the two lenses may be fixed; hence, a linear motor found in some cell phone cameras to perform autofocusing is no longer needed. The two lenses may operate together to combine their focal power and enhance the tuning range of the focus, or they may operate in a parfocal mode to provide zooming capabilities while maintaining independent control of focus. In one or more embodiments, one or both of the variable lenses include the DEA/POE device of FIG. 8.

FIG. 10 illustrates two variable lenses in a head-mounted optical system, where one lens is used for each eye. This may provide capabilities such as eyeglass zooming, on-the-fly tuning of an eyeglass prescription (e.g., for persons suffering from presbyopia), or a focused reflection of side projected images to generate virtual reality or augmented reality experiences. In one or more embodiments, one or both of the variable lenses include the DEA/POE device of FIG. 8.

A combination of DEA with POE facilitates development of devices with long sought-after capabilities, such as dynamic and high-speed tuning, which can be done with voltage- or current-resolved precision in an analog or digital manner in a millisecond (ms) time scale. For example, the DEA/POE techniques of the present disclosure facilitate embedded optical zoom for chip-scale image sensors (e.g., mobile phone cameras). For another example, the DEA/POE techniques of the present disclosure facilitate optical zoom and adaptive focus with lightweight form factors, such as for head mounted optics (e.g., everyday eyeglasses, or virtual reality or augmented reality hardware), heads-up displays, projectors, and optical disc drives. In yet further examples, the DEA/POE techniques of the present disclosure facilitate optical zoom and focal plane scanning for cameras, telescopes, and microscopes without a need for motorized parts. In addition, the flat construction and lateral actuation of DEA/POE device allows for stackable systems to form compound optics. As can be seen in the figures, the DEA/POE techniques of the present disclosure can be used in a wide variety of devices to replace or augment a wide variety of optical elements.

With respect to metasurface POE lenses, a focal length of metasurface lenses stretched as described is variable. In contrast to scaling in traditional optics, where parameters generally scale linearly with size, the focal length of a metasurface POE lens scales as the quadratic function of stretch (s²), yielding large changes in focal length with small DEA spacer strain.

Further, a good focus can be maintained while the POE is stretched. Spherical aberration can be quantified as a deviation of a resulting phase profile of a stretched metasurface from an ideal hyperbolic phase function. Calculations reveal that uniform stretching introduces a very small initial spherical aberration; however, upon further stretching, a built-in suppression of spherical aberration comes into effect, which can be mathematically expressed to follow the quartic function of the ratio of the in-plane radial distance to the stretch factor ((r/s)⁴). The aberration introduced to the phase profile by stretching to the lowest order is:

$$Δ φ \approx {k}_{0} \frac{{r}^{4}}{8 {f}^{3}} ( \frac{1}{{s}^{6}} - \frac{1}{{s}^{4}} ) + O ( {r}^{5} )$$

where r is the radial coordinate, k₀ is the free space wavenumber, f is the designed focal length of the unstretched device, and s is the stretch factor. This allows for highly stretchable, highly variable lens devices with immunity to aberration.

A wide range of common and exotic variable optical elements are possible using the concepts described in the present disclosure, such as, without limitation, axicons, geometric phase devices, variable angle deflectors (scaled linear phased arrays), and scaled holograms (does not affect a wavelength dependence of holograms). The concepts of the present disclosure also make possible new types of POE devices, such as, without limitation, devices for wavefront correction, spatial light modulation, and other types of adaptive optics.

Thus has been described by way of example several embodiments of the concepts of the present disclosure. It is to be understood that the described examples are non-limiting, and other embodiments are within the scope of the present disclosure. Additional examples follow.

An electrically-variable optical device includes a POE and a capability to stretch the POE by applying a voltage or current to a portion of the electrically-variable optical device.

In one or more embodiments, the electrically-variable optical device includes at least one optical layer and at least one electromechanical portion. The electrically-variable optical device may further include a cladding layer. The various layers of the electrically-variable optical device may be stacked and may further be interleaved, and one or more of the layers may be embedded in others of the layers. An electrical power source establishes a potential difference across the electromechanical layer or between electromechanical layers to actuate the electromechanical layer, resulting in stretching of the optical layer.

In one or more embodiments, the POE includes multiple individual elements. Such individual elements may be rigid and spaced apart, so that they maintain their shape when the optical layer is stretched, and the space between individual elements can be expanded according to the stretching; and in another embodiment, the individual elements are compliant, so that they change shape when the optical layer is stretched. A change in shape of individual elements may result in a change in each optical response. The individual elements may have subwavelength dimensions (e.g., a dimension smaller than a wavelength of light for which the POE is designed). The individual elements may have wavelength dimensions or larger (e.g., a dimension equal to or greater than a wavelength of light for which the POE is designed). Ones of the individual elements of the POE may have different dimensions than others of the individual elements of the POE. With respect to spacing of the individual elements, a center-to-center distance between the elements may be fixed (e.g., at rest, prior to stretching), or an edge-to-edge distance between elements may be fixed (e.g., at rest, prior to stretching), or spacing may be irregular.

The POE may be operated in a transmission or a reflection mode. An outside boundary of the POE may be any shape, such as, without limitation, circular or other elliptical shape, or square or other rectangular shape or other polygonal shape. The POE is made of any suitable material or combination of one or more materials, such as, for example, amorphous silicon, silicon dioxide, titanium dioxide, gold, silver, platinum, aluminum, polymer, metal, transparent ceramic, composite material, doped silicon dioxide, borosilicate glass (e.g., BK7 glass, borofloat 33 glass, Corning Eagle glass, or D263 glass), toughened glass (e.g., gorilla glass), single crystal quartz, soda lime glass, silicon, germanium, germanium dioxide, titanium dioxide, sapphire, silicon on insulator, silicon on sapphire, gallium nitride on sapphire, gallium arsenide, gallium phosphide, gallium antimonide, indium phosphide, indium antimonide, indium arsenide, indium gallium arsenide, silicon carbide, lithium niobate, lithium tantalate, vanadium dioxide, yttria alumina garnet, or zirconium dioxide.

The POE may be designed for any wavelength or range of wavelengths of interest, and may be designed to be very narrow band (e.g., nearly single wavelength), narrowband, broadband, or multi-wavelength. The POE may be designed for use with one or more of visible, near-infrared, mid-infrared or far-infrared wavelengths, or other wavelengths.

The POE may be designed for a particular polarization, such as, for example, linear, circular, or elliptical polarization, and may (or may not) perform a separate action on an orthogonal polarization. The POE may also be designed for partially polarized or unpolarized light.

The POE structure may have a defined spatial pattern determining at each location in the pattern a phase or geometric phase, amplitude, and/or polarization. The POE structure may define a focusing element, such as a lens or an axicon. The POE structure may define or may include a beam deflector (e.g., linear phase gradient), a phased array or metasurface, a photonic crystal, a holographic device, a diffraction grating, a multifocal diffractive lens, a polarizer, a beam splitter (polarizing or non-polarizing), a depolarizer, a diffuser, an optical attenuator (e.g., a neutral density filter, a bandpass filter, or an edgepass filter), a Fabry-Perot resonator, a wave plate or retarder (e.g., an array of birefringent elements comprising a phase plate), a Fresnel zone plate (e.g., a Fresnel imager or Fresnel zone antenna), or an aperture (e.g., a pinhole, iris, diaphragm or pupil).

The electromechanical layer may include an elastomeric and substantially optically transparent membrane with compliant and substantially optically transparent electrodes. The electromechanical layer may be configured such that the shape of the layer is altered upon receipt of an electric voltage or current.

The transparent membrane may be an elastomeric membrane. The elastomeric membrane may be positioned between two or more electrodes, such that applying a potential difference between the electrodes creates an electric field across the membrane that generates a compressive force, which results in stretching of the membrane. The stretching may be uniform throughout the membrane, or may be local and addressable depending on the disposition and shape of the electrodes. Accordingly, one or more of the electrodes may include multiple electrode areas arranged in a pattern.

Stretching induces an in-plane coordinate scaling and out of plane thinning or thickening as determined by a Poisson ratio of the spacer, the deformation of which can be transferred and applied to the optical layer. The configuration of the spacer or electrodes can also be such that the stretching is asymmetric or uniaxial when a voltage or current is applied.

The spacer may be an elastomeric membrane, which may be, or may include, polydimethylsiloxane (PDMS), silicones, acrylics including acrylic elastomers (e.g., VHB 4905 and/or VHB 4910, each produced by 3M Company), polyurethane, or a combination of one or more thereof.

The electrodes may include carbon nanotubes (e.g., SWCNTs), or a material having a high (e.g., greater than about 80%) transmittance of visible light and an ability to conduct sufficient electricity to actuate and thus deform the spacer. Other examples of substantially transparent and substantially conductive materials include but are not limited to the following and combinations thereof: transparent conducting polymers, organic-metallic-organic polymers, poly(N-vinylcarbazole) (PVK), poly(3,4-ethylenedioxythiophene) (PEDOT), and PEDOT doped with polystyrene sulfonic acid (PEDOT:PSS), poly(3,4-ethylenedioxythiophene)-tetramethacrylate (PEDOT-TMA), derivatives of polyacetylene, polyaniline, polypyrrole, or polythiophenes, poly(4,4-dioctylcyclopentadithiophene) doped with 2,3-dichloro-5,6-dicyano-1,4-benzoquinone (DDQ), PEDOT doped with DDQ (PEDOT-DDQ), graphene, transparent conducting oxides such as indium tin oxide (ITO), fluorine doped tin oxide (FTO), aluminum-doped zinc-oxide (AZO), indium-doped cadmium-oxide, barium stannate, strontium vanadate, calcium vanadate, other binary compounds of metal oxides, metallic nanowires, and metal grids, and so on. These can be prepared in arrangements such as a film, a patterned structure (such as a fractal or serpentine shape), or nanofibers, and so on, such that they are suitably compliant.

Electrodes may be any suitable size, shape or structure. Electrodes can be in different configurations such as planar, uniform electrodes in the form of a parallel plate capacitor, electrode rings around a periphery of a lens, or electrodes patterned in an electrically addressable array (e.g., a 1000×1000 array).

The electrically-variable optical device may be nonplanar, such that, although the device may be planar at rest, it does not necessarily maintain a planar shape. Application of a voltage or current results in a change to a spatial curvature of the device (e.g., like inflating a balloon).

The electrically-variable optical device may be used for corrective lenses (e.g., eyeglasses or contact lenses), magnifiers (e.g., a magnifying glass, a microscope, or a beam expander), photographic lenses (e.g., a varifocal lens, a zoom lens, a fisheye lens, an anamorphic lens, a mirror lens (catadioptric lens or reflex lens), a corrector plate (e.g., a full aperture corrector, a sub-aperture corrector, or an aberration corrector), a perspective control lens, or a lens used to introduce optical special effects (e.g., a soft focus lens)), stereoscopic lenses, projection lenses (e.g., image or video projection, photographic reduction, or photolithography).

Multiple electrically-variable optical devices may be stacked. For example, a stack may include multiple electrically-variable flat lenses, where focal lengths of all lenses are tuned or some lenses are tuned and some are not tuned or some are variable and some are not variable. A distance of separation between lenses may be fixed, or may be variable (e.g., by action of an ultrasonic motor, such as a piezoelectric motor, stepper motor, or other linear motor). The stacking may provide for effective variable focus by multiple lenses, the construction of a parfocal lens for which the focal plane is unchanged while the magnification is changed (e.g., an ideal zoom lens), or independent control over focus and magnification, for example. Moreover, the stacking may provide for operation in conjunction to reduce aberrations (e.g., spherical aberration, chromatic aberration, or coma).

Another example of a stacked, multiple electrically-variable optical device is where each electrically-variable optical device in the stack is designed with a phase profile corresponding to a specific term in the Zernike polynomials, defined as:

Zₙ^{m}(r,φ)=Rₙ^{m}(r)cos(mθ) (even)

Zₙ^{-m}(r,φ)=Rₙ^{m}(r)sin(mθ) (odd)

where n is the radial degree, m is the azimuthal degree, r is the radial coordinate, θ is the azimuthal angle, and Rₙ^{m} is the radial polynomial given by:

$${R}_{n}^{m} ( r ) = {\sum }_{k = 0}^{( n - m ) / 2} {( - 1 )}^{k} ( \begin{matrix}n - k \\ k\end{matrix} ) ( \begin{matrix}n - 2 k \\ ( n - m ) / 2 - k\end{matrix} ) {r}^{n - 2 k}$$

In such a configuration, the aberrations of a beam passing through this stack may be precisely controlled to any number of specified terms, such as a stack of 5 devices, 10 devices, or 15 devices or more. One embodiment includes the following five terms of the Zernike polynomials: tip (j=2), tilt (j=3), defocus (j=4), oblique astigmatism (j=5), and vertical astigmatism (j=6), with which the wavefront aberrations of a focused optical beam can be electrically controlled in a manner similar to the focus, X, Y stigmation and aperture adjustment capabilities of the modern scanning electron microscope (SEM). Terms of the Zernike polynomials that are particularly suited for this method include those where the stretch, s, can be cleanly factored out (while ignoring constant terms) after stretching the radial coordinate of the term. The following table provides examples.

| Noll | | Radial | Azimuthal | Zernike term (Z) | Stretched Zernike | Can factor out |
|---|---|---|---|---|---|---|
| index | Classical | degree | degree | | term (Z′) | stretch cleanly |
| (j) | name | (n) | (m) | | | ? (Y/N) |
| 1 | Piston | 0 | 0 | 1 | 1 | N/A |
| 2 | Tip (X-Tilt) | 1 | 1 | 2r cos θ | $2 \frac{r}{s} cos θ$ | Y |
| 3 | Tilt (Y-Tilt) | 1 | −1 | 2r sin θ | $2 \frac{r}{s} sin θ$ | Y |
| 4 | Defocus | 2 | 0 | \sqrt{3}(2r² −1) | $\sqrt{3} ( 2 \frac{{r}^{2}}{{s}^{2}} - 1 )$ | Y |
| 5 | Oblique astigmatism | 2 | −2 | \sqrt{6}2r² sin 2θ | $\sqrt{6} 2 \frac{{r}^{2}}{{s}^{2}} sin 2 θ$ | Y |
| 6 | Vertical astigmatism | 2 | 2 | \sqrt{6}2r²cos 2θ | $\sqrt{6} 2 \frac{{r}^{2}}{{s}^{2}} cos 2 θ$ | Y |
| 7 | Vertical coma | 3 | −1 | \sqrt{8}(3r³ − 2r) sin θ | $\sqrt{8} ( 3 \frac{{r}^{3}}{{s}^{3}} - 2 \frac{r}{s} ) sin θ$ | N |
| 8 | Horizontal coma | 3 | 1 | {square root over (8()}3r³ − 2r) cos θ | $\sqrt{8} ( 3 \frac{{r}^{3}}{{s}^{3}} - 2 \frac{r}{s} ) cos θ$ | N |
| 9 | Vertical trefoil | 3 | −3 | \sqrt{8}r³sin 3θ | $\sqrt{8} \frac{{r}^{3}}{{s}^{3}} sin 3 θ$ | Y |
| 10 | Oblique trefoil | 3 | 3 | \sqrt{8}r³cos 3θ | | Y |
| 11 | Primary spherical | 4 | 0 | {square root over (5()}6r⁴ − 6r² + 1) | $\sqrt{8} \frac{{r}^{3}}{{s}^{3}} cos 3 θ$ | N |
| 12 | Vertical secondary astigmatism | 4 | 2 | \sqrt{10}(4r⁴ − 3r²) cos 2θ | $\sqrt{10} ( 4 \frac{{r}^{4}}{{s}^{4}} - 3 \frac{{r}^{2}}{{s}^{2}} ) cos 2 θ$ | N |
| 13 | Oblique secondary astigmatism | 4 | −2 | \sqrt{10}(4r⁴ − 3r²) sin 2θ | $\sqrt{10} ( 4 \frac{{r}^{4}}{{s}^{4}} - 3 \frac{{r}^{2}}{{s}^{2}} ) sin 2 θ$ | N |
| 14 | Vertical quadrafoil | 4 | 4 | \sqrt{10}2r⁴ cos 4θ | $\sqrt{10 } 2 \frac{{r}^{4}}{{s}^{4}} cos 4 θ$ | Y |
| 15 | Oblique quadrafoil | 4 | −4 | \sqrt{10}2r⁴ sin 4θ | $\sqrt{10 } 2 \frac{{r}^{4}}{{s}^{4}} sin 4 θ$ | Y |

Other terms such as vertical coma and horizontal coma, in which stretch does not factor cleanly, may also be electrically-varied, but may not be straightforward to control, because they may not necessarily retain their mathematical orthogonality with respect to the other terms of the Zernike polynomials.

One or more electrically-variable optical devices may be used in conjunction with conventional lenses or mirrors as part of a compound lens optical system.

In an imaging system or other optical system, focusing may be by way of a manual focusing mechanism (e.g., a wheel, button, screw, switch, slider, or computer control) that allows for manual tuning of voltage or current and hence tuning of focal length. Focusing may be an electrical feedback mechanism that adjusts a voltage or current and hence focal length to perform autofocusing, where the feedback may be provided by, for example, measuring a distance from the imaging system to an object by means of sound waves (e.g., ultrasonic), light (e.g., infrared), or phase detection, by contrast detection, or by an assist lamp (e.g., with an autofocus illuminator to provide extra light in performing phase detection or contrast detection). Feedback may be used in a closed-loop control system or an open-loop control system. A hybrid autofocus system may be used, in which autofocus is achieved by a combination of autofocus mechanisms. A control system may perform trap focus (e.g., focus trap or catch-in-focus) in which the action of a subject moving into the focal plane activates the acquisition of an image.

A control system may maintain focus on a subject of interest (e.g., focus tracking) by adjusting the voltage or current and hence the focus in accordance with the distance or appearance of a subject. For example, the focus or focal plane may be scanned across multiple lengths in a continuous or discrete manner.

A confocal microscope configuration may be used, such as to perform three-dimensional imaging. A degree of defocusing or power transmitted can be used to encode information.

Some further non-limiting uses for the electrically-variable optical device include: catoptric (reflection-based) systems, dioptric (transmission-based) systems, catadioptric (hybrid reflection and transmission based) systems, photographic cameras, cell phone cameras, video cameras, search lights, headlamps, optical telescopes, microscopes, telephoto lenses, microlens arrays, head-mounted optics systems, image sensors, endoscopes, machine vision applications, phased arrays, lasers, lenslet arrays, lithotripsy devices, medical imagers, dichroic filters and/or mirrors, and combinations thereof.

The electrically-variable optical device may be incorporated into other electrically-variable optical devices and systems. Non-limiting examples include use in a fiber coupler, a variable coupler, a mode converter, a collimator, an optical modulator, an optical phase shifter, a polarization state generator, a polarimeter, an ellipsometer, a spectrometer, an interferometer, an optical chopper, a fast change optical filter, an optical tweezer, a phase compensator, an adaptive optic, a noise eater, a laser amplitude stabilizer, a vortex plate for generating light beams with orbital angular momentum, a Q plate, an optical power concentrator, and an optical disc drive.

Similar to a POE, a planar element may be designed as a planar acoustic element (PAE), such as by the use of acoustic metamaterials, in order to shape the wavefront of acoustic waves, such as ultrasonic waves.

As used herein, the singular terms “a,” “an,” and “the” may include plural referents unless the context clearly dictates otherwise.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated by such arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, two numerical values can be deemed to be “substantially” the same if a difference between the values is less than or equal to ±10% of an average of the values, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations do not limit the present disclosure. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. An electrically-variable optical device comprising:
a planar optical element (POE) comprising at least one optical layer; and
at least one electromechanical layer configured to spatially deform the POE to change an optical parameter of the POE.

2. The electrically-variable optical device of claim 1, wherein the optical parameter is a focal length.

3. The electrically-variable optical device of claim 1, further comprising an electrical power source configured to establish a potential difference across the at least one electromechanical layer to actuate the at least one electromechanical layer and thereby spatially deform the POE.

4. The electrically-variable optical device of claim 1, wherein the POE comprises a plurality of individual elements arranged to collectively define an aperture size and a spatial profile of phase, amplitude, polarization or a combination of phase, amplitude and polarization.

5. The electrically-variable optical device of claim 1, wherein the POE comprises one of, or a combination of one or more of, amorphous silicon, silicon dioxide, titanium dioxide, gold, silver, platinum, aluminum, polymer, metal, transparent ceramic, composite material, doped silicon dioxide, borosilicate glass, toughened glass, single crystal quartz, soda lime glass, silicon, germanium, germanium dioxide, titanium dioxide, sapphire, silicon on insulator, silicon on sapphire, gallium nitride on sapphire, gallium arsenide, gallium phosphide, gallium antimonide, indium phosphide, indium antimonide, indium arsenide, indium gallium arsenide, silicon carbide, lithium niobate, lithium tantalate, vanadium dioxide, yttria alumina garnet, or zirconium dioxide.

6. The electrically-variable optical device of claim 1, wherein the electromechanical layer comprises an elastomeric and substantially optically transparent membrane and substantially optically transparent electrodes, wherein the electromechanical layer is configured such that a shape of the electromechanical layer is altered upon receipt of a voltage.

7. The electrically-variable optical device of claim 6, wherein the elastomeric membrane is between two or more electrodes, such that applying a potential difference between the electrodes creates an electric field across the membrane that generates a compressive force, which results in stretching of the membrane.

8. The electrically-variable optical device of claim 7, wherein at least one of the two or more electrodes comprises a plurality of electrode areas configured to provide local and addressable stretching of the membrane.

9. The electrically-variable optical device of claim 8, wherein electrode areas are controlled such that the electrically-variable optical device is capable of activating different combinations of one or more of the electrode areas, wherein each combination of one or more of the electrode areas is designed with a phase profile that corresponds to a term in a Zernike polynomial, such that each combination provides at least one of tip, tilt, defocus, oblique astigmatism, vertical astigmatism, vertical trefoil, oblique trefoil, vertical quadrafoil, or oblique quadrafoil, to provide electrical control over aberration terms of a wavefront of an optical beam.

10. The electrically-variable optical device of claim 7, wherein at least one of the two or more electrodes is an electrode ring around the POE.

11. The electrically-variable optical device of claim 1, wherein the electromechanical layer includes single-walled carbon nanotubes as electrodes.

12. The electrically-variable optical device of claim 1, wherein the electrically-variable optical device is one of multiple electrically-variable optical devices in a stack, each electrically-variable optical device in the stack comprising a POE, and each POE is designed with a phase profile that corresponds to a term in a Zernike polynomial, such that each electrically-variable optical device in the stack provides at least one of tip, tilt, defocus, oblique astigmatism, vertical astigmatism, vertical trefoil, oblique trefoil, vertical quadrafoil, or oblique quadrafoil, to provide electrical control over aberration terms of a wavefront of an optical beam.

13. The electrically-variable optical device of claim 1, further comprising a flexible and conformal substrate, wherein the POE and the electromechanical layer are disposed on the substrate.

14. The electrically-variable optical device of claim 12, wherein the substrate is an optical contact lens.

15. The electrically-variable optical device of claim 13, wherein the optical contact lens is implantable.

16. The electrically-variable optical device of claim 1, wherein the POE comprises one or more variable focal length metalenses.

17. An optical device, comprising:
a planar optical element (POE) comprising at least one optical layer;
at least one electromechanical layer; and
a power supply configured to apply an electric field across the at least one electrometrical layer; and
wherein the electric field actuates the at least one electromechanical layer to spatially deform the POE to change an optical parameter of the POE.

18. The optical device of claim 17, wherein the at least one electromechanical layer includes a dielectric elastomer actuator (DEA), and the DEA includes electrodes and an elastomeric spacer between the electrodes.

19. The optical device of claim 17, wherein the optical parameter of the POE is a focal length of the POE.

20. The optical device of claim 17, wherein the POE is configured to operate in a transmission mode or in a reflection mode.
